(19) United States
(12) Patent Application Publication
(10) Pub. No.: US 2025/0264325 A1
(43) Pub. Date: Aug. 21, 2025

(54) METHOD FOR PROCESSING WORKPIECE AND MEASUREMENT SYSTEM

(71) Applicant: SINTOKOGIO, LTD., Nagoya-shi (JP)

(72) Inventors: Tatsuya Aoki, Nagoya-shi (JP); Akihiro Kawamoto, Nagoya-shi (JP); Takumi Takeuchi, Nagoya-shi (JP); Hidenori Morita, Nagoya-shi (JP); Norimasa Ishii, Nagoya-shi (JP)

(73) Assignee: SINTOKOGIO, LTD., Nagoya-shi (JP)

(21) Appl. No.: 19/050,421

(22) Filed: Feb. 11, 2025

(30) Foreign Application Priority Data
Feb. 15, 2024 (JP) 2024-021344

(51) Int. Cl. G01B 11/06; B24C 1/08

(52) U.S. Cl. CPC G01B 11/0625; B24C 1/086

(57) ABSTRACT

A method for processing a workpiece, includes, a preparation step of providing a resist film with an opening on a processing surface of the workpiece, a processing step of removing a processing portion of the workpiece exposed by the opening while protecting a protection portion of the workpiece covered by the resist film provided on the workpiece, a measuring step of measuring an overall height from the processing portion of the workpiece to an upper surface of the resist film after the processing step, and a calculating step of calculating a processing amount of the workpiece based on the overall height measured and a thickness of the resist film after the processing step.

### CROSS-REFERENCE TO RELATED APPLICATION

This application is based on Japanese Patent Application No. 2024-021344 filed with Japan Patent Office on Feb. 15, 2024, the entire contents of which are hereby incorporated by reference.

### TECHNICAL FIELD

The present disclosure relates to a method for processing workpiece and a measurement system.

### BACKGROUND

Japanese laid-open application publication No. 2006-065000 discloses a method for processing a workpiece. In this method, a resist film is attached to the workpiece, a pattern is formed on the resist film, the entire workpiece is subjected to sandblasting, and finally, the resist film is removed with an alkaline stripping solution.

### SUMMARY

From the perspective of quality control, it is necessary to confirm whether the workpiece has been processed to the designed shape before removing the resist film. For example, after sandblasting, it is conceivable to temporarily remove the resist film manually to measure the amount of processing. When the processing amount is insufficient, the resist film is reattached, and sandblasting is performed again. This ensures the quality of the workpiece. However, the process of removing and reattaching the resist film requires skilled techniques, is time-consuming, and hinders automation. The present disclosure provides a technology that can calculate the processing amount without removing the resist film.

A method for processing a workpiece according to one aspect of the present disclosure includes a preparation step, a processing step, a measuring step, and a calculating step. The preparation step includes providing a resist film with an opening on a processing surface of the workpiece. The processing step includes removing a processing portion of the workpiece exposed by the opening while protecting a protection portion of the workpiece covered by the resist film provided on the workpiece. The measuring step includes measuring an overall height from the processing portion of the workpiece to an upper surface of the resist film after the processing step. The calculating step includes calculating a processing amount of the workpiece based on the overall height measured and a thickness of the resist film after the processing step.

A measurement system according to another aspect of the present disclosure includes a measuring device and a control unit. The measuring device measures an overall height from a processing portion of a workpiece exposed by an opening to an upper surface of a resist film covering a protection portion of the workpiece. The control unit is connected to the measuring device and calculates a processing amount of the workpiece. The control unit causes the measuring device to measure the overall height from the processing portion of the workpiece to the upper surface of the resist film after processing in which the processing portion of the workpiece is removed while protecting the protection portion of the workpiece, and calculates the processing amount of the workpiece based on the overall height measured and a thickness of the resist film after the processing in which the processing portion of the workpiece is removed.

According to the present disclosure, it is possible to calculate the processing amount without removing the resist film.

### BRIEF DESCRIPTION OF THE DRAWINGS

FIG. 1 is a diagram illustrating an example of a processing system to which a method for processing a workpiece according to an embodiment is applied.

FIG. 2 is a flowchart illustrating a method for processing a workpiece according to an embodiment.

FIGS. 3A to 3E are diagrams illustrating an example of a workpiece in each step.

FIG. 4 is a diagram illustrating dimensions of the workpiece.

### DETAILED DESCRIPTION

Embodiments of the present disclosure will be described in detail with reference to the drawings. In the description of the drawings, the same elements are designated with the same reference signs, and redundant descriptions will be omitted. The dimensional ratios in the drawings do not necessarily match those in the description. The terms “upper,” “lower,” “left,” and “right” are based on the illustrated state and are for convenience.

### [Example of Processing System]

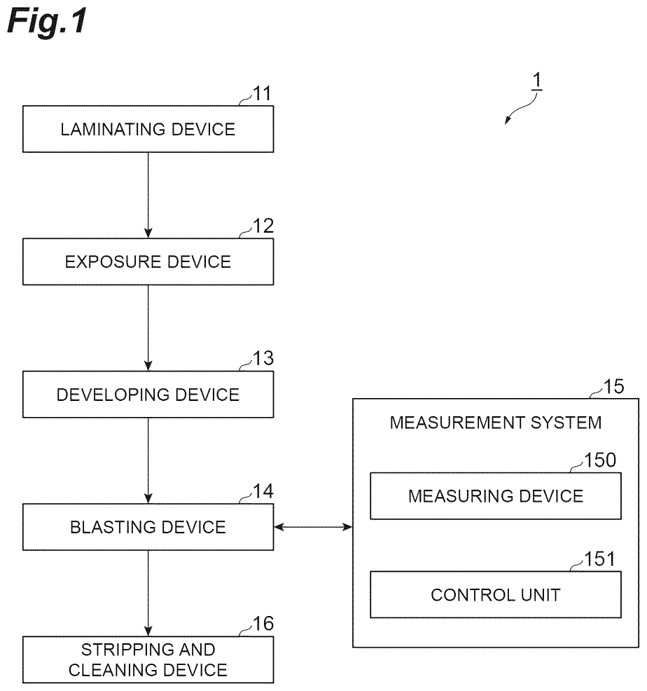

FIG. 1 is a diagram illustrating an example of a processing system to which a method for processing a workpiece according to an embodiment is applied. The processing system 1 shown in FIG. 1 is composed of a group of devices for processing a workpiece. The workpiece is, for example, a plate-like member. Specific examples of the workpiece include an electrostatic chuck for holding a substrate, a glass substrate, a ceramic substrate, and/or a silicon substrate. The processing system 1 performs processing to remove the surface of the workpiece. Specific examples of the processing include forming protrusions on the workpiece, forming holes, and/or forming grooves. The processing method is not particularly limited as long as it can remove the surface of the workpiece. Specific examples of the processing method include sandblasting and/or etching. Hereinafter, a case where the processing system 1 forms protrusions on a plate-like workpiece by sandblasting to manufacture an electrostatic chuck will be described as an example.

The processing system 1 includes a laminating device 11, an exposure device 12, a developing device 13, a blasting device 14, a measurement system 15, and a stripping and cleaning device 16.

The laminating device 11 is a device for attaching a resist film to the upper surface of the workpiece. The resist film is made of a material resistant to the abrasive grains of the sandblasting. The resist film is formed of a resin as an example. The laminating device 11 includes a supply unit for supplying the resist film and a roller for crimping the supplied resist film to the workpiece. The workpiece processed by the laminating device 11 is conveyed to the exposure device 12.

The exposure device 12 is a device for transferring a pattern to the resist film. The exposure device includes a light source that emits light of a specific wavelength such as ultraviolet light and a mask having a pattern to be transferred to the resist film. The workpiece processed by the exposure device 12 is conveyed to the developing device 13.

The developing device 13 is a device for chemically processing the exposed resist film to form a pattern. The developing device 13 includes a nozzle for injecting developing solution and a spin coater for rotating the workpiece. The workpiece processed by the developing device 13 is conveyed to the blasting device 14.

The blasting device 14 is a device for processing the surface by injecting abrasive grains onto the surface of the workpiece at high pressure. The blasting device 14 includes a compressor for supplying compressed air, a hopper for storing abrasive grains, a nozzle connected to the compressor and the hopper for injecting the abrasive grains, a stage for supporting the workpiece, a chamber for accommodating the nozzle and the stage, and an abrasive grain recovery mechanism. The blasting device 14 performs processing according to the set processing conditions. The processing conditions may include the injection amount, processing time (injection time), and/or injection speed. The workpiece processed by the blasting device 14 is once conveyed to the measurement system 15.

The measurement system 15 is a system for calculating the processing amount of the workpiece. The measurement system 15 includes a measuring device 150 and a control unit 151.

The measuring device 150 is a device for measuring the overall height from the processing portion of the workpiece to the upper surface of the resist film. The measuring device 150 is a 3D (three-dimensional) sensor capable of measuring film thickness. Specific examples of the measuring device 150 include a white light interferometer and/or a laser microscope. The white light interferometer irradiates the workpiece with white light and analyzes the interference pattern of the reflected light to measure the overall height from the processing portion of the workpiece to the upper surface of the resist film. The laser microscope irradiates the workpiece with laser light and analyzes the intensity or phase change of the reflected light to measure the overall height from the processing portion of the workpiece to the upper surface of the resist film.

The control unit 151 is connected to the measuring device 150 and calculates the processing amount of the workpiece. The control unit 151 is configured as a computer system including, for example, a processor such as a CPU (Central Processing Unit), a memory such as RAM (Random Access Memory) and ROM (Read Only Memory), input/output devices such as a touch panel, a mouse, a keyboard, and a display, and communication devices such as a network card. The control unit 151 realizes the functions described later by operating each hardware based on a program stored in the memory or the like.

The control unit 151 is configured to operate the measuring device 150. The control unit 151 calculates the processing amount of the workpiece based on the measurement result of the measuring device 150. The method for calculating the processing amount of the workpiece will be described later. The control unit 151 may feed back the measurement result to the blasting device 14. For example, the control unit 151 transmits a signal to the blasting device 14 to change the processing conditions of the blasting device 14 based on the measurement result.

The measurement system 15 may include a spectroscopic film thickness meter in addition to the measuring device 150. The 3D sensor, which is the measuring device 150, may not be able to measure the film thickness of the resist film depending on the transmittance of the resist film. The spectroscopic film thickness meter has a light source that emits light of a predetermined wavelength and can measure the thickness of the resist film based on the intensity of the reflected light from the surface and the back surface of the resist film and the refractive index of the resist film. The workpiece measured by the measurement system 15 is conveyed to the blasting device 14. The workpiece measured by the measurement system 15 may be conveyed to the stripping and cleaning device 16.

The stripping and cleaning device 16 is a device for stripping and cleaning the resist film from the workpiece. The stripping and cleaning device 16 includes a tank for storing the stripping solution and a nozzle for spraying the stripping solution. The workpiece is finished as a product by the stripping and cleaning device 16.

As described above, the processing system 1 shown in FIG. 1 processes the workpiece in sequence. The workpiece may be conveyed between the devices by a robot or by an operator. By adopting robot conveyance, the entire process can be automated.

### [Example of Method for Processing Workpiece]

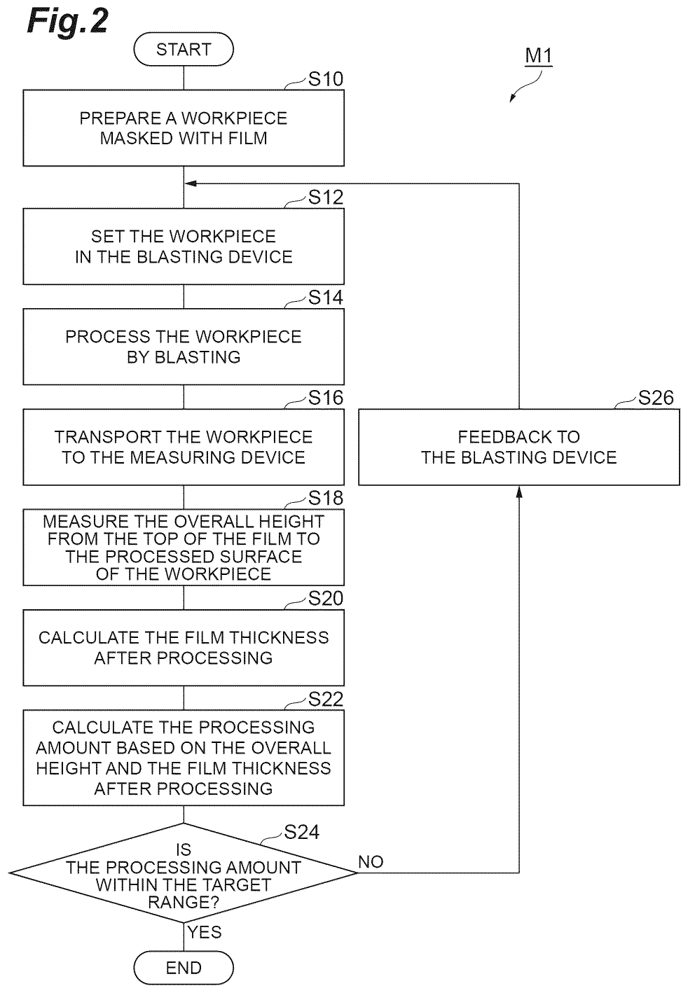

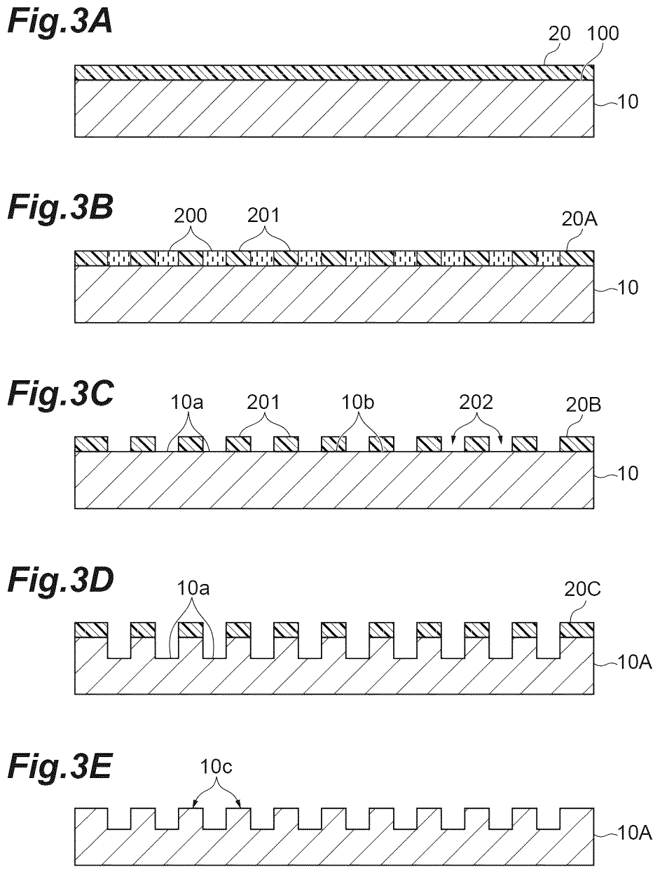

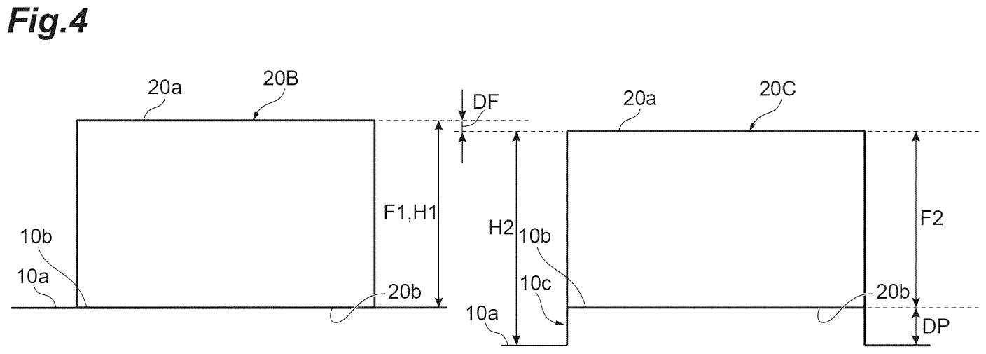

FIG. 2 is a flowchart illustrating a method for processing a workpiece according to an embodiment. The processing method M1 shown in FIG. 2 is executed by the processing system 1. In the description of the processing method, reference is made to FIGS. 3A to 3E and FIG. 4. FIGS. 3A to 3E are diagrams illustrating an example of a workpiece in each step. FIG. 4 is a diagram illustrating dimensions of the workpiece.

As shown in FIG. 2, first, in step S10 (an example of the preparation step), a workpiece masked with a resist film is prepared. The workpiece masked with the resist film is the workpiece just before the sandblasting. FIGS. 3A to 3C illustrate the workpiece prepared in step S10.

First, as shown in FIG. 3A, the resist film 20 is supplied from the film supply unit of the laminating device 11, and the resist film 20 is crimped to the processing surface 100 of the workpiece 10 by the roller. Next, as shown in FIG. 3B, light of a specific wavelength such as ultraviolet light is projected onto the resist film 20 from the light source of the exposure device 12 through the mask. The exposed resist film 20 chemically changes to become the resist film 20A in which a soluble region 200 and an insoluble region 201 are formed. Next, as shown in FIG. 3C, the developing solution is supplied onto the exposed resist film 20A from the nozzle of the developing device 13. As a result, the resist film 20A becomes the resist film 20B in which the soluble region 200 is dissolved to form the opening 202 and the insoluble region 201 remains. The processing surface 100 of the workpiece 10 has a processing portion 10a exposed by the opening 202 and a protection portion 10b covered with the resist film 20B. The workpiece shown in FIG. 3C is the workpiece masked with the resist film and is the workpiece just before the processing step.

Subsequently, in step S12, the workpiece is set on the stage of the blasting device 14. Subsequently, in step S14 (processing step), the processing portion 10a of the workpiece 10 is removed while protecting the protection portion 10b of the workpiece 10 with the resist film 20B. As a more specific example, abrasive grains are injected toward the workpiece 10 from the nozzle of the blasting device 14. As a result, as shown in FIG. 3D, the workpiece 10 becomes the workpiece 10A in which the processing portion 10a of the workpiece 10 is removed (cut), and the resist film 20B becomes the resist film 20C with the upper surface worn.

As shown in FIG. 4, before the processing step, the thickness F1 of the resist film 20B provided on the workpiece is the same as the overall height H1 from the processing portion 10a of the workpiece to the upper surface 20a of the resist film 20B. In the processing step, when the processing portion 10a of the workpiece 10 is removed, the upper surface of the resist film 20B is also worn to some extent. After the processing step, the sum of the thickness F2 of the resist film 20C and the wear amount DF of the resist film is the same as the thickness F1 of the resist film 20B (or the overall height H1), and the sum of the thickness F2 of the resist film 20C and the processing amount DP is the same as the overall height H2 from the processing portion 10a of the workpiece to the upper surface 20a of the resist film 20C.

Subsequently, in step S16, the workpiece 10A provided with the resist film 20C is conveyed from the blasting device 14 to the measuring device 150. In step S18, the measuring device 150 measures the overall height H2 from the processing portion 10a of the workpiece to the upper surface 20a of the resist film 20C.

Subsequently, in step S20, the control unit 151 calculates the thickness F2 of the resist film 20C. Then, in step S22 (calculating step), the control unit 151 calculates the processing amount DP based on the thickness F2 of the resist film 20C. The following two methods exist.

The first method is a method of calculating the processing amount DP by subtracting the thickness F2 of the resist film 20C from the overall height H2 from the processing portion 10a of the workpiece to the upper surface 20a of the resist film 20C. The thickness F2 of the resist film 20C is measured by a spectroscopic film thickness meter separately included in the measuring device 150, for example. As a specific example, the thickness of the resist film 20C is measured based on the intensity of the reflected light from the surface and the back surface of the resist film 20C and the refractive index of the resist film 20C. Since the thickness F2 of the resist film 20C is directly measured, the accurate processing amount DP can be calculated compared to the case where the thickness F2 of the resist film 20C is calculated or estimated.

The second method is a method of calculating the processing amount DP by calculating the wear amount DF, calculating the thickness F2 of the resist film 20C from the wear amount DF, and subtracting the thickness F2 of the resist film 20C from the overall height H2 from the processing portion 10a of the workpiece to the upper surface 20a of the resist film 20C.

First, before the processing step, the measuring device 150 measures the overall height H1 (thickness F1 of the resist film 20B) from the processing portion 10a of the workpiece 10 to the upper surface of the resist film 20B (pre-measuring step). That is, the pre-measuring step is executed in step S10 (preparation step).

Next, the control unit 151 calculates the wear amount DF. The storage unit of the control unit 151 stores the wear amount of the resist film 20 per unit injection amount in advance. The control unit 151 calculates the wear amount DF by multiplying the injection amount of the abrasive grains in step S14 (processing step) by the wear amount of the resist film 20 per unit injection amount. Then, the control unit 151 calculates the thickness F2 of the resist film 20C by subtracting the wear amount DF from the overall height H1 (thickness F1 of the resist film 20B) from the processing portion 10a of the workpiece 10 to the upper surface of the resist film 20B. Then, the control unit 151 calculates the processing amount DP by subtracting the thickness F2 of the resist film 20C from the overall height H2 from the processing portion 10a of the workpiece to the upper surface 20a of the resist film 20C. According to the second method, even if the thickness F2 of the resist film 20C cannot be directly measured due to the relationship between the refractive index and the transmittance, the processing amount DP can be calculated.

When the processing amount DP is calculated, in step S24, the control unit 151 determines whether the processing amount DP is within the target range. The target range is set to include the target processing amount, for example. When it is determined that the processing amount DP is not within the target range (step S24: NO), the control unit 151 changes the processing conditions of the next processing step in step S26 (feedback step). By feeding back the measurement result to the processing conditions, the workpiece is processed to the designed shape. When it is determined that the processing amount DP is within the target range (step S24: YES), the flowchart shown in FIG. 2 ends.

When the flowchart shown in FIG. 2 ends, a stripping and cleaning step (not shown) is executed. FIG. 3E is a diagram illustrating an example of a workpiece in the stripping and cleaning step. In the stripping and cleaning step, the stripping solution is sprayed onto the entire workpiece 10A from the nozzle of the stripping and cleaning device 16. As a result, the resist film 20C is stripped off, and the workpiece 10A is obtained as a product.

### Summary of Embodiment

In the processing method M1 and the measurement system 15, the workpiece 10 is prepared, and the processing portion 10a of the workpiece 10 is removed using the resist film 20B. Thereafter, the overall height H2 from the processing portion 10a of the workpiece 10A to the upper surface 20a of the resist film 20C is measured. Next, the processing amount of the workpiece 10A is calculated based on the measured overall height H2 and the thickness F2 of the resist film 20C after the processing step. In the processing method M1 and the measurement system 15, the processing amount is calculated without removing the resist film 20C. Therefore, it is not necessary to remove or reattach the resist film 20C to measure the processing amount, which eliminates the need for skilled techniques and reduces manpower and time.

As described above, various exemplary embodiments have been described, but the present disclosure is not limited to the above-described exemplary embodiments, and various omissions, substitutions, and changes may be made. For example, the measurement system 15 may be integrated with the blasting device 14. As an example, the measuring device 150 may be disposed inside the chamber of the blasting device 14. Even in such a configuration, the same effects as those of the processing method M1 and the measurement system 15 can be obtained. Also, the refractive index of the resist film 20 may be unknown. In this case, the thickness F1 of the resist film 20B may be measured by the 3D sensor or the spectroscopic film thickness meter, and the overall height H1 may be measured by the 3D sensor, and the refractive index of the resist film 20 may be derived by dividing the thickness F1 of the resist film 20B by the overall height H1. The processing method M1 and the measurement system 15 may calculate the processing amount of the workpiece 10A using the derived refractive index of the resist film 20.

What is claimed is:

1. A method for processing a workpiece, comprising:
a preparation step of providing a resist film with an opening on a processing surface of the workpiece;
a processing step of removing a processing portion of the workpiece exposed by the opening while protecting a protection portion of the workpiece covered by the resist film provided on the workpiece;
a measuring step of measuring an overall height from the processing portion of the workpiece to an upper surface of the resist film after the processing step; and
a calculating step of calculating a processing amount of the workpiece based on the overall height measured and a thickness of the resist film after the processing step.

2. The method for processing the workpiece according to claim 1, wherein in the calculating step, the thickness of the resist film after the processing step is measured based on an intensity of reflected light from a surface and a back surface of the resist film and a refractive index of the resist film.

3. The method for processing the workpiece according to claim 1, wherein the preparation step includes a pre-measuring step of measuring the overall height from the processing portion of the workpiece to the upper surface of the resist film before the processing step as a thickness of the resist film before the processing step;
the processing step includes injecting abrasive grains onto the workpiece; and
in the calculating step, a wear amount of the resist film in the processing step is calculated based on an injection amount of the abrasive grains and a wear amount of the resist film per unit injection amount, and the thickness of the resist film after the processing step is calculated based on the thickness of the resist film before the processing step and the wear amount of the resist film.

4. The method for processing the workpiece according to claim 1, further comprising a feedback step of changing processing conditions of next processing step based on the processing amount of the workpiece calculated in the calculating step and a target processing amount.

5. A measurement system comprising:
a measuring device for measuring an overall height from a processing portion of a workpiece exposed by an opening to an upper surface of a resist film covering a protection portion of the workpiece; and
a control unit connected to the measuring device for calculating a processing amount of the workpiece,
wherein the control unit causes the measuring device to measure the overall height from the processing portion of the workpiece to the upper surface of the resist film after processing in which the processing portion of the workpiece is removed while protecting the protection portion of the workpiece, and calculates the processing amount of the workpiece based on the overall height measured and a thickness of the resist film after the processing in which the processing portion of the workpiece is removed.
